(19) United States
(12) Patent Application Publication
(10) Pub. No.: US 2010/0148364 A1
(43) Pub. Date: Jun. 17, 2010

(54) SEMICONDUCTOR DEVICE AND METHOD FOR PRODUCING SEMICONDUCTOR DEVICE

(76) Inventor: Masahiro OKITA, Osaka-shi (JP)

Correspondence Address: NIXON & VANDERHYE, PC, 901 NORTH GLEBE ROAD, 11TH FLOOR, ARLINGTON, VA, 22203, US

(21) Appl. No.: 12/633,898

(22) Filed: Dec. 9, 2009

(30) Foreign Application Priority Data
Dec. 11, 2008 (JP) 2008-315754

(51) Int. Cl. H01L 23/49; H01L 21/60; H01L 23/498

(52) U.S. Cl. 257/738; 257/784; 438/617; 257/E21.509; 257/E23.024; 257/E23.06

(57) ABSTRACT

A semiconductor device includes: a substrate having an external electrode formed thereon, the external electrode being capable of being electrically connected to an outside; and a semiconductor element having a surface electrode formed thereon, the surface electrode being made from an electrically conducting paste, the semiconductor element being mounted on the substrate, the external electrode being electrically connected by wire bonding to the surface electrode via a connecting member. This provides (i) a semiconductor device including: a substrate having an external electrode capable of being electrically connected to an outside; and a semiconductor element having a surface electrode made from an electrically conducting paste, the semiconductor device allowing for assured bonding reliability and a simplified means or step of connecting the surface electrode to the external electrode, and (ii) a method for producing the semiconductor device.

This Nonprovisional application claims priority under 35 U.S.C. §119(a) on Patent Application No. 2008-315754 filed in Japan on Dec. 11, 2008, the entire contents of which are hereby incorporated by reference.

### TECHNICAL FIELD

The present invention relates to a semiconductor device and a method for producing the semiconductor device. More particularly, the present invention relates to a technique of connecting, by wire bonding, (i) a surface electrode on a semiconductor element such as a solar cell to (ii) an external electrode of a substrate on which the semiconductor element is mounted, wherein the semiconductor element includes no wiring layer inside.

### BACKGROUND ART

Conventionally, there has been widely known a semiconductor device including a semiconductor element mounted on a substrate and sealed with resin. In semiconductor devices of this type, the substrate has an external electrode on a surface thereof to which the semiconductor element is bonded. The external electrode is, for example, a lead terminal, and is capable of being electrically connected to an outside of the semiconductor device. Further, the semiconductor element has a surface electrode on a surface opposite from a surface via which the semiconductor element is bonded to the substrate. The surface electrode is electrically connected to the external electrode on the substrate. The surface electrode of the semiconductor element is connected to the external electrode on the substrate by, for example, wire bonding via a gold wire.

Such connection between the surface electrode on the semiconductor element and the external electrode on the substrate requires high reliability. However, since the semiconductor element in a semiconductor device and the gold wire are sealed together with resin after the wire bonding, the gold wire would be detached sometimes. In view of this, the following measures have been taken to establish the connection between the external electrode and the gold wire more surely. (see, for example, Patent Literatures 1 and 2). In one configuration, the surface electrode has a rough surface so as to improve adhesion between the surface electrode and the gold wire, a surface of the external electrode is plated, or a conductive adhesive is applied to a surface of the external electrode. This allows the gold wire to be bonded to the plated surface or the conductive adhesive, thereby assuring the connection between the external electrode and the gold wire.

The surface electrode is normally made of aluminum (Al) or an aluminum alloy by, e.g., sputtering or deposition. Thus, for a semiconductor element such as an IC or an LSI, which includes a wiring layer formed by an IC production process or an LSI production process, the same process may be employed to form its surface electrode. However, sputtering and deposition require a large-scale facility and high processing costs.

In contrast, for a semiconductor element (e.g., a solar cell) including no wiring layer, a surface electrode thereof is formed by printing an electrically conducting paste. This aims to reduce facility costs and improve mass productivity. In order to electrically connect the surface electrode to the external electrode, this arrangement widely adopts soldering a solder-coated aluminum ribbon to the surface electrode and the external electrode. (see, for example, Patent Literature 3).

FIG. 7 is a view illustrating an arrangement of a conventional semiconductor device 100 including a semiconductor element 105 having a surface electrode 106 made from an electrically conducting paste.

As illustrated in FIG. 7, the conventional semiconductor device 100 includes: a substrate 101 having a substrate electrode 102 and an external electrode 103 capable of being electrically connected to an outside; and the semiconductor element 105 having the surface electrode 106 formed by sintering the electrically conducting paste. The semiconductor element 105 is mounted via a solder 104 on the substrate electrode 102 formed on the substrate 101. The surface electrode 106 on the semiconductor element 105 is electrically connected to the external electrode 103 on the substrate 101 with an aluminum ribbon 107 which is coated with a solder. In this way, the aluminum ribbon 107 is reliably bonded to the surface electrode 106 made of the electrically conducting paste.

### Citation List

Patent Literature 1

Japanese Patent Application Publication, Tokukai, No. 2004-111628 A (Publication Date: Apr. 8, 2004)

Patent Literature 2

Japanese Patent Application Publication, Tokukaihei, No. 5-136317 A (Publication Date: Jun. 1, 1993)

Patent Literature 3

Japanese Patent Application Publication, Tokukai, No. 2007-305876 A (Publication Date: Nov. 22, 2007)

### SUMMARY OF INVENTION

### Technical Problem

The conventional semiconductor device 100 requires flux application before reflow-soldering the aluminum ribbon 107. This necessitates washing to remove the remaining flux after the reflow-soldering. Further, the aluminum ribbon 107 needs to be fixedly positioned during heating. This requires setting up a jig to fix the aluminum ribbon 107. As a result, connecting the surface electrode 106 on the semiconductor element 105 to the external electrode 103 on the substrate 101 requires numerous man-hours (steps).

The present invention has been accomplished in view of the above conventional problems. It is an object of the present invention to provide a semiconductor device and a method for producing the semiconductor device, in each of which the semiconductor device includes a substrate having an external electrode capable of being electrically connected to an outside; and a semiconductor element having a surface electrode made from an electrically conducting paste, and each of which provides a simplified means or step for reliably bonding the surface electrode to the external electrode.

### Solution to Problem

In order to solve the above problems, a semiconductor device of the present invention includes: a substrate having an external electrode formed thereon, the external electrode being capable of being electrically connected to an outside; and a semiconductor element having a surface electrode formed thereon, the surface electrode being made from an electrically conducting paste, the semiconductor element being mounted on the substrate, the external electrode being electrically connected to the surface electrode via a connecting member by wire bonding.

In order to solve the above problems, a method of the present invention for producing a semiconductor device, the semiconductor device including: a substrate having an external electrode formed thereon, the external electrode being capable of being electrically connected to an outside; and a semiconductor element having a surface electrode formed thereon, the surface electrode being made from an electrically conducting paste, the semiconductor element being mounted on the substrate, the method including electrically connecting the external electrode to the surface electrode via a connecting member by wire bonding.

According to the above arrangement and method, the external electrode on the substrate is electrically connected to the surface electrode on the semiconductor element by wire bonding via the connecting member. This eliminates the need to use flux and thus eliminates the step of removing flux. Further, the bonding can be performed without the need for fixedly holding the connecting member. Thus, it is possible to perform high-speed bonding with high bonding reliability. Consequently, the means or step of connecting the surface electrode to the external electrode can be simplified without losing the bonding reliability.

### ADVANTAGEOUS EFFECTS OF INVENTION

As described above, the semiconductor device of the present invention is configured such that the external electrode on the substrate is electrically connected to the surface electrode on the semiconductor element via the connecting member by wire bonding.

The method of the present invention for producing the semiconductor device includes electrically connecting the external electrode on the substrate to the surface electrode on the semiconductor element via the connecting member by wire bonding.

The present invention as arranged above makes it possible not only to assure bonding reliability, but also to simplify a means or step of connecting a surface electrode to an external electrode, in a semiconductor device or a method of producing the semiconductor device, in which the semiconductor device includes: a substrate having the external electrode capable of being electrically connected to an outside; and a semiconductor element having the surface electrode made from an electrically conducting paste.

### BRIEF DESCRIPTION OF DRAWINGS

FIG. 1 is a view illustrating semiconductor device in accordance with one embodiment of the present invention.

FIG. 2 (a) is a view illustrating a process of producing the semiconductor device.

FIG. 2 (b) is a view illustrating the process of producing the semiconductor device.

FIG. 2 (c) is a view illustrating the process of producing the semiconductor device.

FIG. 2 (d) is a view illustrating the process of producing the semiconductor device.

FIG. 3 (a) is a view illustrating an alternative process of producing the semiconductor device.

FIG. 3 (b) is a view illustrating the alternative process of producing the semiconductor device.

FIG. 3 (c) is a view illustrating the alternative process of producing the semiconductor device.

FIG. 3 (d) is a view illustrating the alternative process of producing the semiconductor device.

FIG. 4 is a view illustrating how a surface electrode of a semiconductor element and an initial ball are positionally related with each other during first bonding for the semiconductor device.

FIG. 5 is a graph showing respective bond strengths for different post-compression-bond diameters attained with initial balls having different diameters in the semiconductor device.

FIG. 6 (a) is a cross-sectional view illustrating a part at which an initial ball is bonded to the surface electrode on the semiconductor element of the semiconductor device.

FIG. 6 (b) is an enlarged view of a portion of FIG. 6 (a), the portion being surrounded by a dashed line

FIG. 7 is a view illustrating an arrangement of a conventional semiconductor device.

### DESCRIPTION OF EMBODIMENTS

One embodiment of the present invention is described below with reference to the drawings.

(Arrangement of Semiconductor Device)

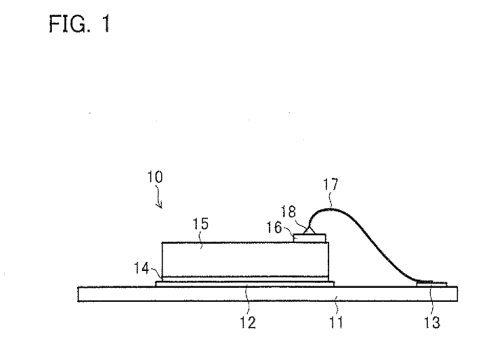

FIG. 1 is a view illustrating an exemplary arrangement of a semiconductor device 10 according to the present embodiment.

As illustrated in FIG. 1, the semiconductor device 10 includes a substrate 11 and a semiconductor element 15. Note that FIG. 1 schematically illustrates constituent members of the semiconductor device 10 that are relevant to the present invention. Therefore, such members are focused in FIG. 1. Thus, the semiconductor device 10 is, for example, packaged by being sealed with resin, even though this is not illustrated in FIG. 1.

The substrate 11 is not particularly limited to any specific type, provided that it is an insulating substrate excelling in heat resistance. The substrate 11 is, for example, a resin substrate made of, e.g., glass epoxy. The substrate 11 has a surface to which the semiconductor element 15 is mounted. This surface, to which the semiconductor element 15 is mounted, is hereinafter referred to as a “mounting surface.” On the mounting surface, the substrate 11 has a substrate electrode 12 and an external electrode 13. The substrate electrode 12 is disposed in a region in which the semiconductor element 15 is mounted. The external electrode 13 is disposed outside the region in which the semiconductor element 15 is mounted. The external electrode 13 is, for example, a lead terminal (lead), and is capable of being electrically connected to an outside of the semiconductor device 10. The semiconductor device 10 includes at least one external electrode 13.

In FIG. 1, the substrate 11 is illustrated as if it has an exposed portion on which no member for electrical connection is provided. The portion is coated with an insulating solder resist (not shown). The substrate 11 may have a multilayer structure, or may be so configured that the external electrode 13 is connected via internal wiring to a ball-shaped external connection terminal provided on a surface opposite from the mounting surface.

The semiconductor element 15, configured as a semiconductor chip, is made from e.g., silicon. The semiconductor element 15 includes an element or elements inside thereof so as to be variously functioned. The semiconductor element 15 has, on a surface, at least one surface electrode 16. The semiconductor element 15 is mounted onto the substrate electrode 12 on the substrate 11 via a solder 14. The semiconductor element 15 is mounted onto the substrate electrode 12 in such a manner that the surface on which the surface electrode 16 is formed faces above, whereas a surface opposite from the above surface faces the substrate electrode 12. Instead of the solder 14, an adhesive may be used, for example.

The surface electrode 16 is made from an electrically conducting paste. Specifically, the surface electrode 16 is formed by printing an electrode material (i.e., the electrically conducting paste) on the surface of the semiconductor element 15. The electrically conducting paste is silver (Ag) paste, which can be sintered at a low temperature (e.g., at 800° C. or lower). The surface electrode 16 is electrically connected to the external electrode 13 via a gold wire 17 (connecting member) by ball bonding in the wire bonding process.

More specifically, the semiconductor device 10 is configured such that the surface electrode 16 and the external electrode 13 are, as described below, connected by ball bonding. In the ball bonding, an end of the gold wire 17 is melted so as to form an initial ball 18 in a ball shape, and the initial ball 18 is heated under load and ultrasonic application so that the initial ball 18 is compression-bonded to its target. The ball bonding is firstly performed to connect the gold wire 17 to the surface electrode 16 (first bonding), and secondly the ball bonding is performed to connect the gold wire 17 to the external electrode 13 (second bonding).

As described above, the semiconductor device 10 includes the semiconductor element 15 including no wiring layer. The semiconductor element 15 is, for example, a solar cell. When the semiconductor element 15 is a solar cell, the semiconductor device 10 can be produced as a solar cell panel (solar cell module).

The semiconductor device 10 does not necessarily include a single semiconductor element 15 mounted on a substrate 11. Thus, it may include multiple semiconductor elements 15 mounted on a substrate 11. Further, the semiconductor device 10 may also include, for each specific application, other electronic components such as a capacitor and a resistor on the substrate 11.

(Method for Producing Semiconductor Device)

The following describes in detail a method for producing the semiconductor device 10 having the above arrangement.

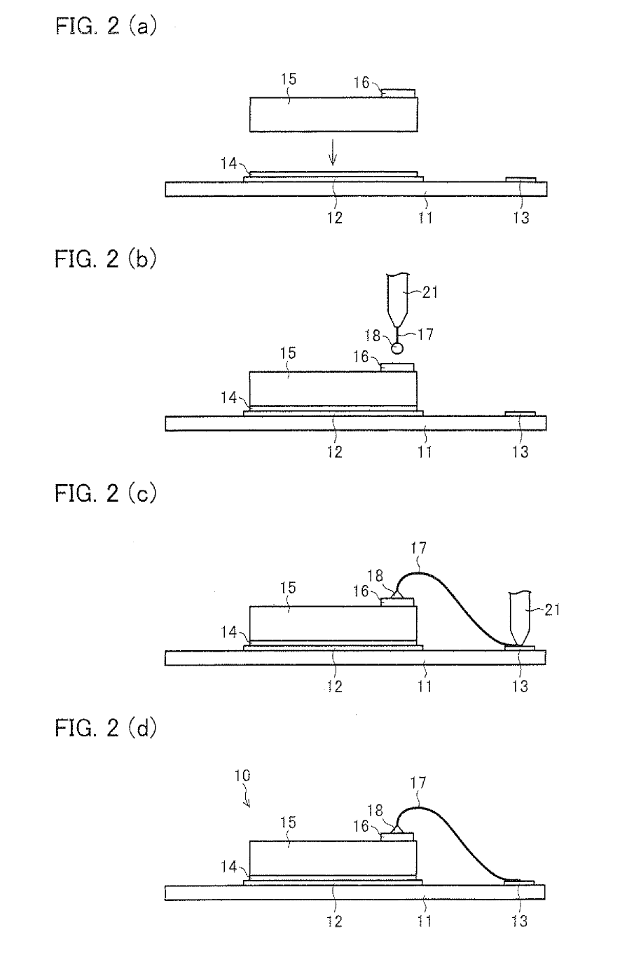

FIGS. 2 (a) through 2 (d) are views illustrating a process of producing the semiconductor device 10.

First, the substrate 11 and the semiconductor element 15 are prepared. They may each be produced by a conventionally known method. Then, as illustrated in FIG. 2 (a), the semiconductor element 15 is mounted onto the substrate 11. Specifically, a solder paste (solder 14) is printed onto the substrate electrode 12 on the substrate 11. The printing of the solder paste is performed by a printer with use of a steel plate mask and a squeegee. Then, the semiconductor element 15 is mounted on the solder paste. By using a reflow device, the solder paste is then melted and solidified, whereby the semiconductor element 15 is fixed to the substrate 11. In this way, the semiconductor element 15 is so mounted that the surface on which the surface electrode 16 is formed faces above.

Next, as illustrated in FIG. 2 (b), the first bonding is performed on the surface electrode 16 on the semiconductor element 15. Specifically, the ball bonding in the wire bonding process is performed by using an ultrasonic thermocompression wire bonder, for example. The wire bonder includes a capillary 21 that holds a gold wire 17 in such a manner that the gold wire 17 can be continuously fed from the capillary 21. First, an end of the gold wire 17 is melted so as to form an initial ball 18 in a ball shape. Then, the capillary 21, which holds the gold wire 17, is moved to a position above the surface electrode 16 on the semiconductor element 15. The capillary 21 is then lowered toward the surface electrode 16. The initial ball 18 is compression-bonded to the surface electrode 16 by applying heat, pressure, and ultrasonic wave to the gold wire 17. As a result, the initial ball 18 is bonded to the surface electrode 16.

Then, as illustrated in FIG. 2 (c), the second bonding is performed on the external electrode 13 on the substrate 11. Specifically, after the first bonding step, the capillary 21 is raised from the surface electrode 16. Then, the capillary 21 is moved to a position above the external electrode 13 on the substrate 11. The capillary 21 is then lowered toward the external electrode 13. Here, the gold wire 17 is looped as appropriate. The gold wire 17 is compression-bonded to the external electrode 13 by applying heat, pressure, and ultrasonic wave to the gold wire 17. As a result, the gold wire 17 is bonded to the external electrode 13. After the second bonding, the capillary 21 is raised from the external electrode 13. Then, the gold wire 17 is cut.

As illustrated in FIG. 2 (d), the above causes the surface electrode 16 on the semiconductor element 15 to be electrically connected by ball bonding to the external electrode 13 on the substrate 11 via the gold wire 17. Further, the ball bonding is performed in the same manner sequentially on other pairs of a surface electrode 16 and an external electrode 13 that need to be connected to each other. After the above connecting step, a conventionally known production step, such as a step of resin molding with use of a mold, is performed, so that the semiconductor device 10 is finished.

As described above, the semiconductor device 10 of the present embodiment includes: the substrate 11 having the external electrode 13 formed on it, the external electrode 13 being capable of being electrically connected to an outside; and the semiconductor element 15 having the surface electrode 16 formed on it, the surface electrode 16 being made from an electrically conducting paste, the semiconductor element 15 being mounted on the substrate 11, the external electrode 13 on the substrate 11 being electrically connected to the surface electrode 16 on the semiconductor element 15 via the gold wire 17 by ball bonding in wire bonding.

In other words, the semiconductor device 10 of the present embodiment is produced by such a method that includes electrically connecting, via the gold wire 17, the external electrode 13 on the substrate 11 to the surface electrode 16 on the semiconductor element 15 by ball bonding in wire bonding.

The external electrode 13 on the substrate 11 is electrically connected to the surface electrode 16 on the semiconductor element 15 via the gold wire 17 by ball bonding in wire bonding. This eliminates the need to use flux and thus eliminates the step of removing flux. The above further eliminates the need to fix the gold wire 17 for bonding. Thus, it is possible to assure bonding reliability and also to perform bonding rapidly. Consequently, it is possible to not only assure bonding reliability but also to simplify the means or step of connecting the surface electrode 16 to the external electrode 13. In addition, it is also possible to prevent increase in the processing cost.

The wire bonding is not limited to ball bonding, and may thus be any type of wire bonding, even though the above method for producing the semiconductor device 10 adopts ball bonding for wire bonding. The above method uses a gold wire, which can be used in ball bonding, in order to reduce a bonding area. However, depending on a current amount, an aluminum wire may be used to perform wedge bonding or an aluminum ribbon may be used to perform ribbon bonding, instead of the gold wire. Further, the ball bonding for the surface electrode 16 and the ball bonding for the external electrode 13 may be performed in any order, even though the ball bonding is performed firstly on the surface electrode 16 on the semiconductor element 15 in the production method described above.

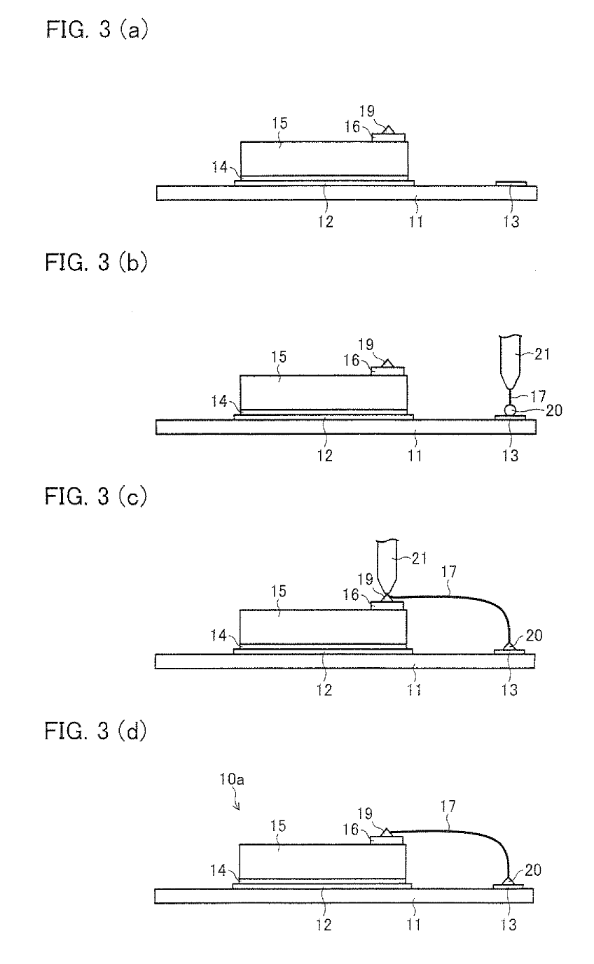

FIGS. 3 (a) through 3 (d) are views illustrating a production process that involves ball bonding whose first bonding is performed on the external electrode 13 on the substrate 11.

First, as illustrated above in FIG. 2 (a), the semiconductor element 15 is mounted above the substrate 11. Then, as illustrated in FIG. 3 (a), a stud bump 19 is formed on the surface electrode 16 on the semiconductor element 15. Specifically, the process uses a wire bonder including a capillary 21 that holds a gold wire 17. An end of the gold wire 17 is melted so as to form a ball. Then, the capillary 21 is moved to a position above the surface electrode 16 on the semiconductor element 15. The capillary 21 is then lowered toward the surface electrode 16. The ball-shaped end is compression-bonded to the surface electrode 16 by applying heat, pressure, and ultrasonic wave to the gold wire 17. After the compression bonding, the capillary 21 is raised from the surface electrode 16. Then, the gold wire 17 is cut. As a result, a stud bump 19 is formed which is bonded to the surface electrode 16.

Then, as illustrated in FIG. 3 (b), the first bonding is performed on the external electrode 13 on the substrate 11. Specifically, by use of the method described above with reference to FIG. 2 (b), an initial ball 20 is formed at an end of the gold wire 17, and is compression-bonded to the external electrode 13. As a result, the initial ball 20 is bonded to the external electrode 13.

Next, as illustrated in FIG. 3 (c), a second bonding is performed on the stud bump 19 formed on the surface electrode 16 on the semiconductor element 15. Specifically, after the first bonding, the gold wire 17 is looped as appropriate. The gold wire 17 is then bonded to the stud bump 19. After this bonding, the gold wire 17 is cut.

As illustrated in FIG. 3 (d), this electrically connects the surface electrode 16 on the semiconductor element 15 to the external electrode 13 on the substrate 11 via the gold wire 17 by ball bonding involving the use of the stud bump 19. Further, the ball bonding is performed in the same manner sequentially on other pairs of a surface electrode 16 and an external electrode 13 that need to be connected to each other. The stud bump 19 may be formed on each of multiple surface electrodes 16 on the semiconductor element 15 in advance before the production step illustrated in FIG. 3 (a).

According to a semiconductor device 10a produced by the above method, the loop of the gold wire 17 can be formed at a low position. This allows for a reduction in thickness of the semiconductor device 10a. The above is in turn effective in downsizing various apparatuses including the semiconductor device 10a.

During the bonding, if the capillary 21 comes in contact with the surface electrode 16, the transmission of ultrasonic energy and pressure is prevented. This results in unstable connection. Further, this contact contaminates the tip of the capillary 21. This decreases productivity and also shortens life of the capillary 21. This in turn necessitates properly adjusting the capillary 21 so as to prevent it from coming into contact with the surface electrode 16.

Meanwhile, the surface electrode 16 of the semiconductor device 10 is formed by printing an electrically conducting paste onto a surface of the semiconductor element 15. Specifically, a mesh-like mask is placed on a surface of the semiconductor element 15, and then the electrically conducting paste is printed onto the surface. The electrically conducting paste thus printed has a protruded surface, and consequently, the surface of the surface electrode 16 is protruded. Thus, a possibility of the contact cannot be eliminated even by properly adjusting the capillary 21.

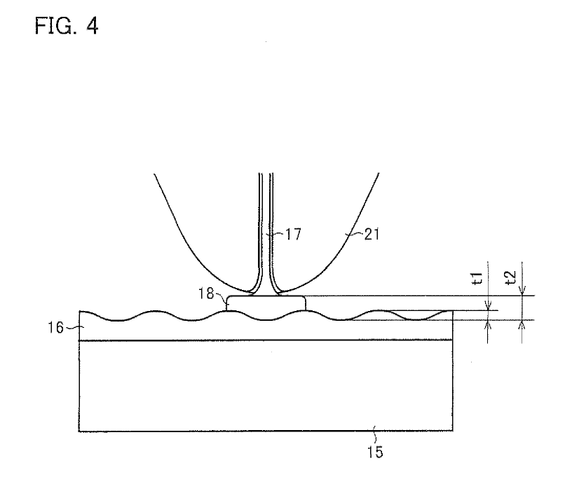

In view of this, the semiconductor device 10 is preferably arranged as follows: respective diameters of (i) the initial ball 18 for the first bonding on the surface electrode 16, and (ii) the stud bump 19 formed on the surface electrode 16, are larger than a height of the protrusion on the surface electrode 16. More specifically, as illustrated in FIG. 4, the respective diameters of the initial ball 18 and the stud bump 19 are larger than a difference (t1) between a thickest portion and a thinnest portion of the surface electrode 16.

This causes the initial ball 18, bonded to the surface electrode 16 through the first bonding, to have a height (t2) larger than a height of the thickest portion of the surface electrode 16. Similarly, the above causes the stud bump 19 formed on the surface electrode 16 to have a height larger than the height of the thickest portion of the surface electrode 16. As a result, it is possible to prevent the capillary 21 from coming into contact with the surface electrode 16.

The semiconductor device 10 is preferably arranged as follows: The initial ball 18 in the first bonding for the surface electrode 16 has a large diameter, and also has a large post-compression-bond diameter after its compression-bonding. This allows for improvement in bonding reliability.

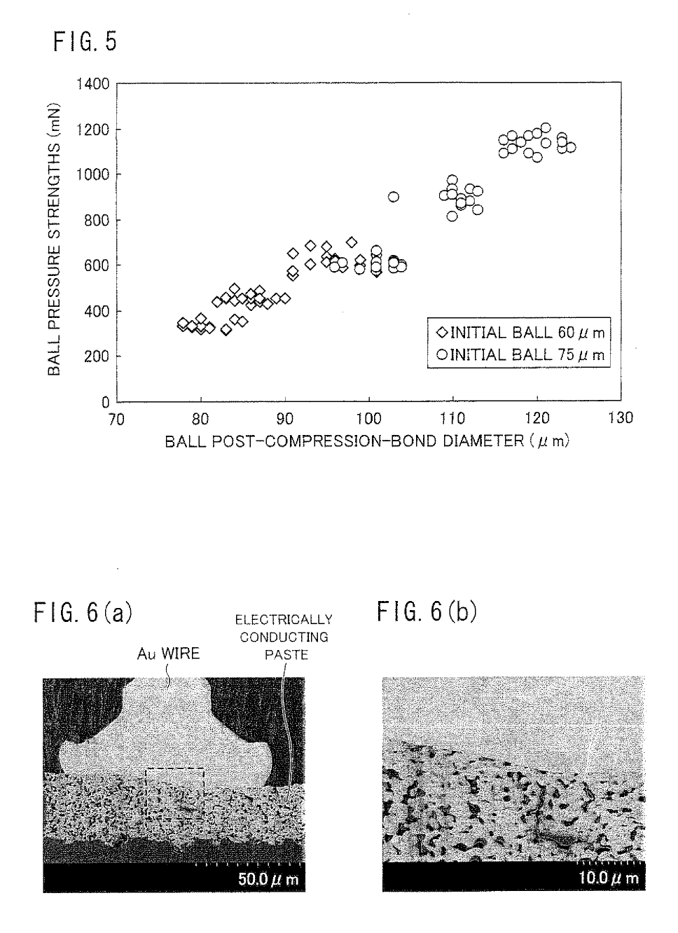

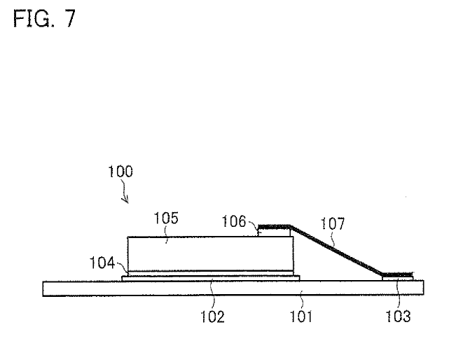

FIG. 5 is a graph showing results of a study on bond strengths (ball pressure strengths) with respect to ball post-compression-bond diameters for initial balls 18 having diameters of 60 μm and 75 μm, respectively. The horizontal axis represents the ball post-compression-bond diameter (μm), whereas the vertical axis represents the ball pressure strength (mN). The square marks (⋄) represent results obtained when the initial ball 18 has a diameter of 60 μm, whereas the circles (∘) represent results obtained when the initial ball 18 has a diameter of 75 μm.

The results of the study shown in FIG. 5 were conducted under the following conditions:

Diameter of the gold wire 17: 25 μm
Temperature of the heater in the wire bonder: 150° C.
Film thickness, the height of protrusion, and a protrusion pitch of the surface electrode 16: approximately 20 μm, approximately 10 μm, and 100 μm, respectively
These dimensions of the surface electrode 16 were measured after printing and sintering the electrically conducting paste. A mesh size of the mask is almost a single factor to determine the protrusion pitch.

FIG. 5 demonstrates that the combination of a larger diameter and a larger post-compression-bond diameter of the initial ball 18 results in a greater bond strength. For example, FIG. 5 demonstrates that when the height of the protrusion of the surface electrode 16 is approximately 10 μm (pitch of 100 μm), the initial ball 18 preferably has a diameter of 75 μm so that its post-compression-bond diameter is large.

FIG. 6 (a) is a cross section of a part at which the initial ball 18 is bonded to the surface electrode 16. The cross section was observed with a SEM. FIG. 6 (b) is an enlarged view of a portion surrounded by a dashed line, shown in FIG. 6 (a).

As illustrated in FIGS. 6 (a) and 6 (b), the gold wire 17 (Au wire) is bonded not to glass frit between silver particles in the surface electrode 16 (conducting paste), but to the silver particles therein. The bonding portion has an area smaller than an area of a bonding portion that would be obtained if the gold wire 17 were bonded to a normal aluminum pad. However, as illustrated in FIG. 5, the ball pressure strength improves in substantial proportion to the ball post-compression-bond diameter.

The above indicates that increasing the ball post-compression-bond diameter allows for improvement in bonding reliability. Note that the initial ball 18 having an excessively large diameter damages the surface electrode 16 and, consequently, damages the semiconductor element 15 as well. This necessitates properly adjusting an upper limit of the diameter.

The present invention is not limited by the description of the embodiment above, but may be altered in various manners within the scope of the claims. Any embodiment based, on a proper combination of technical means achieved by appropriate modifications within the scope of the claims is also encompassed in the technical scope of the present invention.

For example, the semiconductor device of the present invention may preferably be arranged such that the connecting member is a gold wire. The method of the present invention for producing a semiconductor device may preferably be arranged such that the connecting member is a gold wire.

The semiconductor device of the present invention may preferably be arranged such that the wire bonding includes ball bonding. The method of the present invention for producing a semiconductor device may preferably be arranged such that the wire bonding includes ball bonding. This allows the connecting member to be suitably looped.

Further, to reliably bond the connecting member to the surface electrode made from an electrically conducting paste, the semiconductor device of the present invention may preferably be arranged such that first bonding of the ball bonding is performed on the surface electrode. The method of the present invention for producing a semiconductor device may preferably be arranged such that first bonding of the ball bonding is performed on the surface electrode.

The semiconductor device of the present invention may preferably be arranged such that the first bonding is carried out with a ball having a post-bonding height greater than a height of a thickest portion of the surface electrode.

During the bonding, if a tool (e.g., a capillary) that holds the connecting member comes in contact with the surface electrode, the transmission of ultrasonic wave and pressure for the boding is prevented. This renders the bond unstable. Further, the above contact contaminates the tip of the tool. This decreases productivity and also shortens life of the tool. In view of this, the above arrangement prevents the tool holding the connecting member from coming into contact with the surface electrode.

Further, to reliably bond the connecting member to the surface electrode made from an electrically conducting paste, the semiconductor device of the present invention may further include a stud bump formed on the surface electrode, wherein first bonding of the ball bonding is performed on the external electrode; and second bonding of the ball bonding is performed on the stud bump.

The method of the present invention for producing a semiconductor device may also be arranged such that the ball bonding includes: forming a stud bump on the surface electrode; performing first bonding of the ball bonding on the external electrode; and performing second bonding of the ball bonding on the stud bump.

The semiconductor device of the present invention may preferably be arranged such that the stud bump has a height greater than a height of a thickest portion of the surface electrode. This prevents a tool (e.g., a capillary) that holds the connecting member from coming into contact with the surface electrode.

### INDUSTRIAL APPLICABILITY

The present invention is suitably applicable not only to a semiconductor device including a semiconductor element including no wiring layer and mounted above a substrate, but also to a method for producing such a semiconductor device. The semiconductor device of the present invention is useful as, e.g., a solar cell panel (solar cell module), and is thus suitably useable as a power source for practical applications.

### REFERENCE SIGNS LIST

10, 10a semiconductor device
11 substrate
12 substrate electrode
13 external electrode
15 semiconductor element
16 surface electrode
17 gold wire (connecting member)
18 initial ball
19 stud bump
20 initial ball
21 capillary

1. A semiconductor device comprising:
a substrate having an external electrode formed thereon, the external electrode being capable of being electrically connected to an outside; and
a semiconductor element having a surface electrode formed thereon, the surface electrode being made from an electrically conducting paste,
the semiconductor element being mounted on the substrate, and
the external electrode being electrically connected to the surface electrode via a connecting member by wire bonding.

2. The semiconductor device according to claim 1, wherein the connecting member is a gold wire.

3. The semiconductor device according to claim 2, wherein the wire bonding includes ball bonding.

4. The semiconductor device according to claim 3, wherein first bonding of the ball bonding is performed on the surface electrode.

5. The semiconductor device according to claim 4, wherein the first bonding is carried out with a ball having a post-bonding height greater than a height of a thickest portion of the surface electrode.

6. The semiconductor device according to claim 3, further comprising a stud bump formed on the surface electrode,
wherein:
first bonding of the ball bonding is performed on the external electrode; and
second bonding of the ball bonding is performed on the stud bump.

7. The semiconductor device according to claim 6, wherein the stud bump has a height greater than a height of a thickest portion of the surface electrode.

8. A method for producing a semiconductor device,
the semiconductor device including:
a substrate having an external electrode formed thereon, the external electrode being capable of being electrically connected to an outside; and
a semiconductor element having a surface electrode formed thereon, the surface electrode being made from an electrically conducting paste,
the semiconductor element being mounted on the substrate,
the method comprising:
electrically connecting the external electrode to the surface electrode via a connecting member by wire bonding.

9. The method according to claim 8, wherein the connecting member is a gold wire.

10. The method according to claim 9, wherein the wire bonding includes ball bonding.

11. The method according to claim 10, wherein first bonding of the ball bonding is performed on the surface electrode.

12. The method according to claim 10, wherein:
the ball bonding includes:
forming a stud bump on the surface electrode;
performing first bonding of the ball bonding on the external electrode; and
performing second bonding of the ball bonding on the stud bump.
